(19) United States
(12) Patent Application Publication
(10) Pub. No.: US 2006/0292757 A1
(43) Pub. Date: Dec. 28, 2006

(54) Thin-film transistor (TFT) for driving organic light-emitting diode (OLED) and method for manufacturing the same

(75) Inventors: Yung-Fu Wu, Zhonghe City (TW); Yu-Jung Liu, Kaohsiung City (TW); Yung-Hui Yeh, Hsinchu City (TW)

Correspondence Address: BRUCE H. TROXELL;SUITE 1404, 5205 LEESBURG PIKE, FALLS CHURCH, VA, 22041, US

(73) Assignee: Industrial Technology Research Institute

(21) Appl. No.: 11/201,150

(22) Filed: Aug. 11, 2005

(30) Foreign Application Priority Data
Jun. 28, 2005 (TW) 94121544

(51) Int. Cl. H01L 21/84

(52) U.S. Cl. 438/149

(57) ABSTRACT

A thin-film transistor (TFT) and a method for manufacturing the thin-film transistor using a color filter as a dielectric layer so as to drive an organic light-emitting diode. The thin-film transistor comprises: a substrate; a first poly-silicon mesa formed on the substrate; an insulating layer formed on the substrate and covering the first poly-silicon mesa; a gate metal layer formed on the insulating layer; a color-filtering dielectric layer formed on the insulating layer and covering the gate metal layer, the dielectric layer being provided with a plurality of contact holes penetrating through the dielectric layer and the insulating layer; and a conductive layer formed on the dielectric layer and coupled to the first poly-silicon mesa through the contact holes. The method comprises steps of: providing a substrate; forming a first poly-silicon mesa and a second poly-silicon mesa on the substrate; doping the first poly-silicon mesa with an n-type dopant using ion implantation; forming an insulating layer on the substrate, the insulating layer covering the first poly-silicon mesa and the second poly-silicon mesa; forming a gate metal layer on the insulating layer corresponding to the first poly-silicon mesa and the second poly-silicon mesa; doping the first poly-silicon mesa with an n-type dopant using ion implantation; doping the second poly-silicon mesa with a p-type dopant using ion implantation; forming a dielectric layer capable of color filtering on the insulating layer, the dielectric layer covering the gate metal layer; forming a plurality of contact holes in the dielectric layer, the plurality of contact holes penetrating the dielectric layer and the insulating layer so as to contact the first poly-silicon mesa and the second poly-silicon mesa; forming a conductive layer on the dielectric layer; and etching the conductive layer.

### BACKGROUND OF THE INVENTION

1. Field of the Invention

The present invention generally relates to a thin-film transistor (TFT) for driving an organic light-emitting diode (OLED) and a method for manufacturing the thin-film transistor and, more particularly, to a thin-film transistor and a method for manufacturing the thin-film transistor using a color filter as a dielectric layer so as to drive an organic light-emitting diode.

2. Description of the Prior Art

The organic light-emitting diode (OLED) has attracted considerable attention in the flat panel display applications for its high resolution, high quality images and independence from backlight sources. Moreover, in order to avoid incoherent color aging, the OLED has been integrated with different color filters.

The U.S. Pat. No. 6,515,428 discloses an organic light-emitting diode as shown in FIG. 1, which is a cross-sectional view of an organic light-emitting diode. In FIG. 1, the organic light-emitting diode comprises: a substrate 10; a buffer layer 11 formed on the substrate 10; a poly-silicon mesa 12 formed on the buffer layer 11; an oxide layer 13 formed on the poly-silicon mesa 12; a dielectric layer 14 formed on the oxide layer 13; a first conductive layer 15 formed on the dielectric layer 14 and coupled to the poly-silicon mesa 12 through the dielectric layer 14 and the oxide layer 13; a passivation layer 16 formed on the dielectric layer 14; a color filter 17 formed in the passivation layer 16; and a second conductive layer 18 coupled to the first conductive layer 15. An organic light-emitting diode 19 is then formed on the second conductive layer 18. The color filter 17 on the dielectric layer 14 makes manufacturing complicated and difficult, thus increasing the cost.

Moreover, the U.S. Pat. No. 6,037,195 discloses a thin-film transistor as shown in FIG. 2, which is a cross-sectional view of a thin-film transistor. In FIG. 2, the thin-film transistor comprises: a substrate 20; a buffer layer 21 formed on the substrate 20; two poly-silicon mesas 22 formed on the buffer layer 21; an insulating layer 23 formed on the buffer layer 21 and covering the poly-silicon mesas 22; a gate metal layer formed on the insulating layer 23; an oxide layer 24 formed on the insulating layer 23; a first conductive layer 25 formed on the oxide layer 24 and coupled to the poly-silicon mesas 22 through the oxide layer 24 and the insulating layer 23; a passivation layer 26 formed on the oxide layer 24; and a second conductive layer 27 coupled to the first conductive layer 25. Such a thin-film transistor requires multiple photo-lithographical steps and is complicated in manufacturing processes.

Therefore, there is need in providing a thin-film transistor and a method for manufacturing the thin-film transistor using a color filter as a dielectric layer so as to overcome the problems stated above.

### SUMMARY OF THE INVENTION

It is the primary object of the present invention to provide a thin-film transistor and a method for manufacturing the thin-film transistor, using a color filter as a dielectric layer so as to integrate the color filter into the thin-film transistor, thus simplifying the manufacturing process and lowering the cost.

It is the secondary object of the present invention to provide a thin-film transistor and a method for manufacturing the thin-film transistor, using a dielectric layer capable of color filtering with a monochromatic organic light-emitting diode so as to avoid incoherent color aging.

In order to achieve the foregoing objects, the present invention provides a thin-film transistor, comprising: a substrate; a first poly-silicon mesa formed on the substrate; an insulating layer formed on the substrate and covering the first poly-silicon mesa; a gate metal layer formed on the insulating layer; a color-filtering dielectric layer formed on the insulating layer and covering the gate metal layer, the dielectric layer being provided with a plurality of contact holes penetrating through the dielectric layer and the insulating layer; and a conductive layer formed on the dielectric layer and coupled to the first poly-silicon mesa through the contact holes.

It is preferable that the first poly-silicon mesa is p-type or n-type.

It is preferable that if the first poly-silicon mesa is p-type, the thin-film transistor further comprises an n-type second poly-silicon mesa formed on the substrate and covered by the insulating layer, wherein the conductive layer is coupled to the second poly-silicon mesa through the contact holes.

In a first embodiment, the present invention provides a method for manufacturing a thin-film transistor, comprising steps of: providing a substrate; forming a first poly-silicon mesa and a second poly-silicon mesa on the substrate; doping the first poly-silicon mesa with an n-type dopant using ion implantation; forming an insulating layer on the substrate, the insulating layer covering the first poly-silicon mesa and the second poly-silicon mesa; forming a gate metal layer on the insulating layer corresponding to the first poly-silicon mesa and the second poly-silicon mesa; doping the first poly-silicon mesa with an n-type dopant using ion implantation; doping the second poly-silicon mesa with a p-type dopant using ion implantation; forming a dielectric layer capable of color filtering on the insulating layer, the dielectric layer covering the gate metal layer; forming a plurality of contact holes in the dielectric layer, the plurality of contact holes penetrating the dielectric layer and the insulating layer so as to contact the first poly-silicon mesa and the second poly-silicon mesa; forming a conductive layer on the dielectric layer; and etching the conductive layer.

In a second embodiment, the present invention provides a method for manufacturing a thin-film transistor, comprising steps of: providing a substrate; forming a poly-silicon mesa on the substrate; forming an insulating layer on the substrate, the insulating layer covering the poly-silicon mesa; forming a gate metal layer on the insulating layer corresponding to the poly-silicon mesa; doping the poly-silicon mesa with an p-type dopant using ion implantation; forming a dielectric layer capable of color filtering on the insulating layer, the dielectric layer covering the gate metal layer; forming a plurality of contact holes in the dielectric layer, the plurality of contact holes penetrating the dielectric layer and the insulating layer so as to contact the poly-silicon mesa; forming a conductive layer on the dielectric layer; and etching the conductive layer.

It is preferable that the substrate is transparent.

It is preferable that the substrate is made of one material selected from a group comprising glass, plastic, quartz, silicon and stainless steel.

It is preferable that the conductive layer is made of metal.

### BRIEF DESCRIPTION OF THE DRAWINGS

The objects, spirits and advantages of the preferred embodiments of the present invention will be readily understood by the accompanying drawings and detailed descriptions:

FIG. 1 is a cross-sectional view of a conventional organic light-emitting diode;

FIG. 2 is a cross-sectional view of a conventional thin-film transistor;

FIG. 3 to FIG. 13 are cross-sectional views showing a method for manufacturing a thin-film transistor in accordance with a first embodiment of the present invention;

FIG. 14 to FIG. 22 are cross-sectional views showing a method for manufacturing a thin-film transistor in accordance with a second embodiment of the present invention; and

FIG. 23 is a cross-sectional view showing a p-channel thin-film transistor coupled to an organic light-emitting diode in accordance with the present invention.

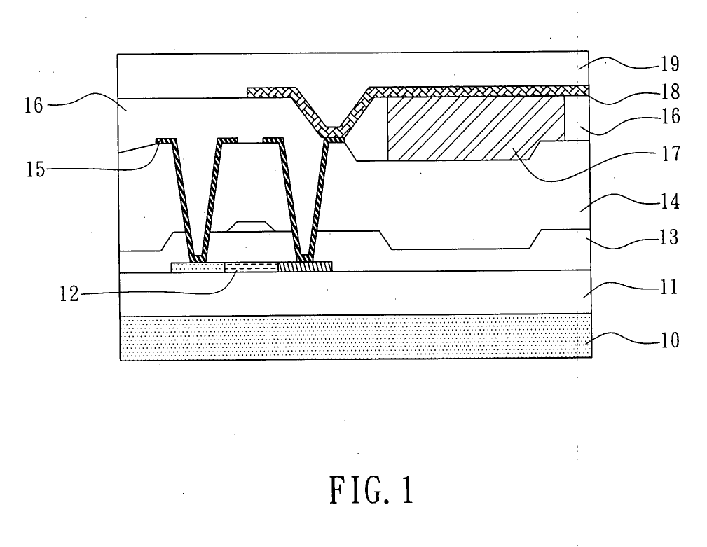

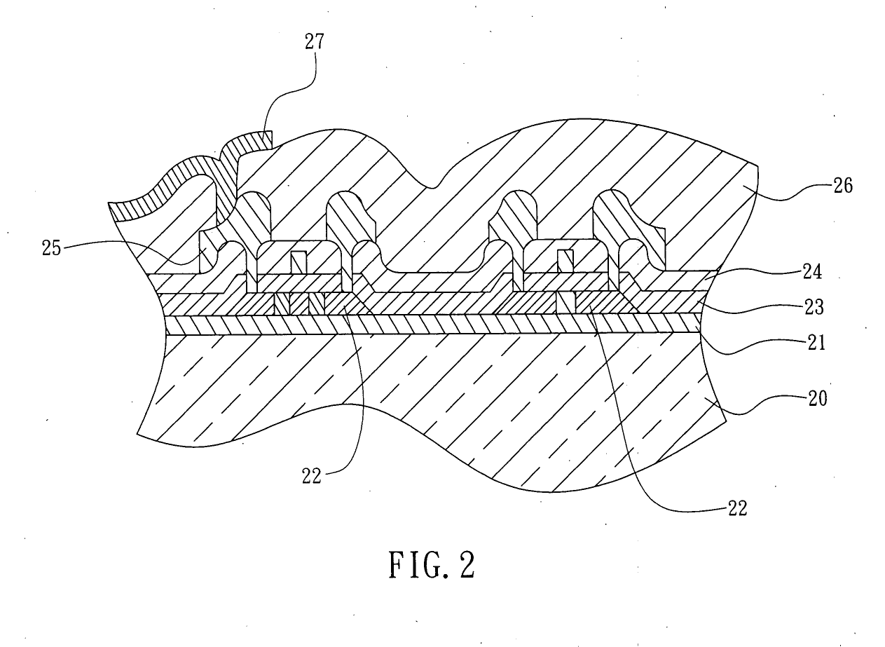

### DETAILED DESCRIPTION OF THE INVENTION

The present invention providing a thin-film transistor (TFT) for driving an organic light-emitting diode (OLED) and a method for manufacturing the thin-film transistor can be exemplified by the preferred embodiments as described hereinafter.

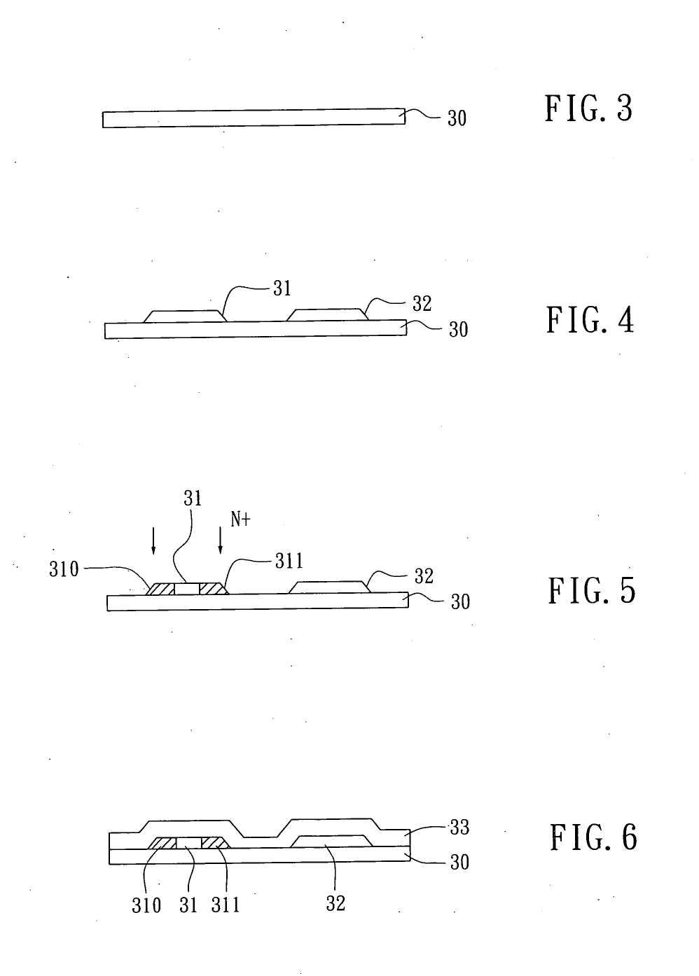

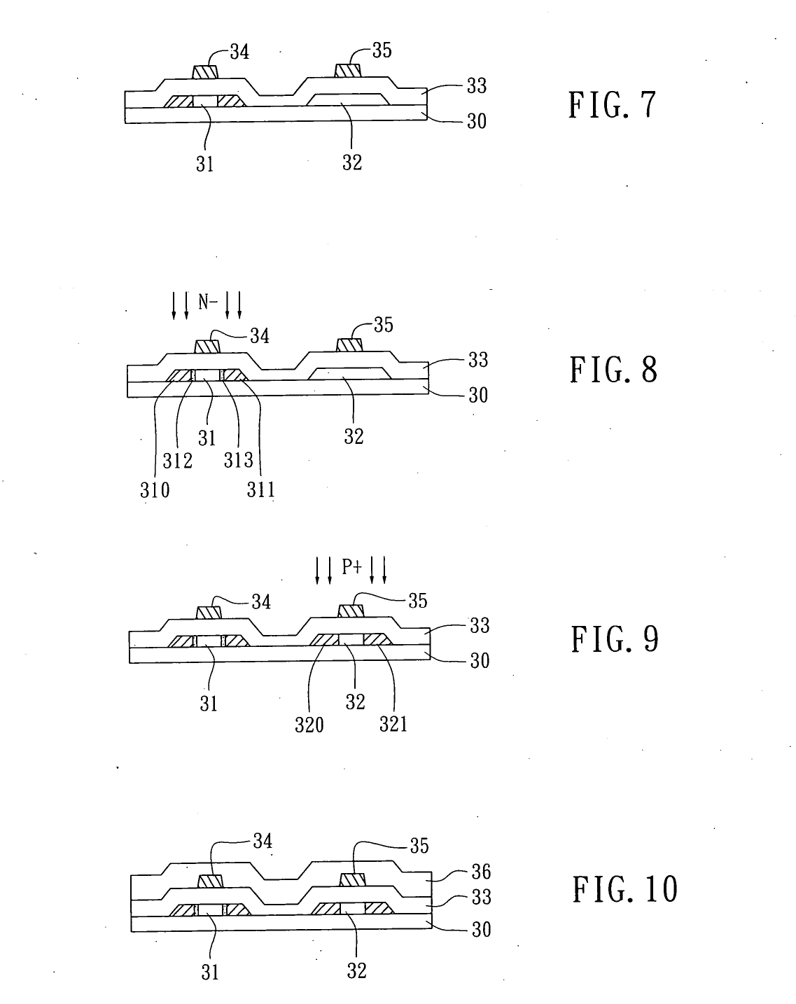

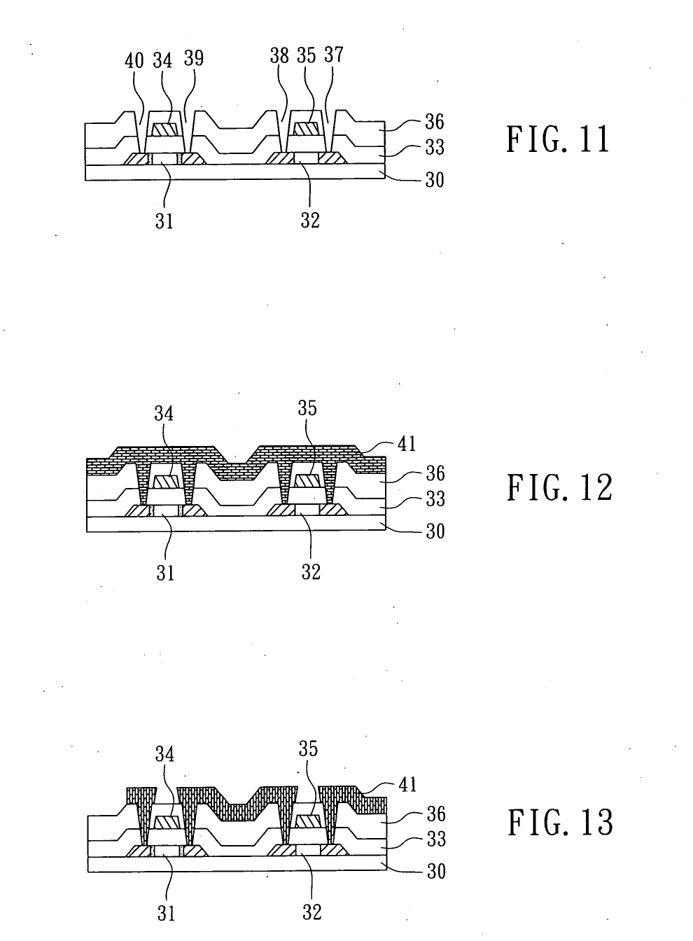

Please refer to FIG. 3 to FIG. 13, which are cross-sectional views showing a method for manufacturing a thin-film transistor in accordance with a first embodiment of the present invention. In FIG. 3, a substrate 30 is provided. In FIG. 4, a first poly-silicon mesa 31 and a second poly-silicon mesa 32 are formed on the substrate 30 using a first mask (not shown). In FIG. 5, the first poly-silicon mesa 31 is doped with an n-type dopant using ion implantation with a second mask (not shown) so as to form electrode regions 310 and 311. Then, an insulating layer 33 is formed on the substrate 30, wherein the insulating layer 33 covers the first poly-silicon mesa 31 and the second poly-silicon mesa 32, as shown in FIG. 6. In FIG. 7, a gate metal layer for two gate electrodes 34 and 35 is formed on the insulating layer 33 corresponding to the first poly-silicon mesa 31 and the second poly-silicon mesa 32 using a third mask (not shown). The first poly-silicon mesa 31 is doped with an n-type dopant using self-aligned ion implantation such that n regions 312 and 313 are formed around the electrode regions 310 and 311, as shown in FIG. 8. In FIG. 9, the second poly-silicon mesa 32 is doped with a p-type dopant using ion implantation using a fourth mask (not shown) such that electrode regions 320 and 321 are formed on the second poly-silicon mesa 32. Then, a dielectric layer 36 capable of color filtering is formed on the insulating layer 33, wherein the dielectric layer 33 covers the gate metal layer for gate electrodes 34 and 35, as shown in FIG. 10. In FIG. 11, a plurality of contact holes 37, 38, 39 and 40 are formed in the dielectric layer 36 using a fifth mask (not shown), wherein the contact holes 37, 38, 39 and 40 penetrate the dielectric layer 36 and the insulating layer 33 so as to contact the first poly-silicon mesa 31 and the second poly-silicon mesa 32. Then, a conductive layer 41 is formed on the dielectric layer 36 so as to cover the dielectric layer 36 and fill the contact holes 37, 38, 39 and 40, as shown in FIG. 12. In FIG. 13, the conductive layer 41 is etched using a sixth mask (not shown) so as to form circuitry required.

Accordingly, only six masks are required to form a complementary thin-film transistor circuit.

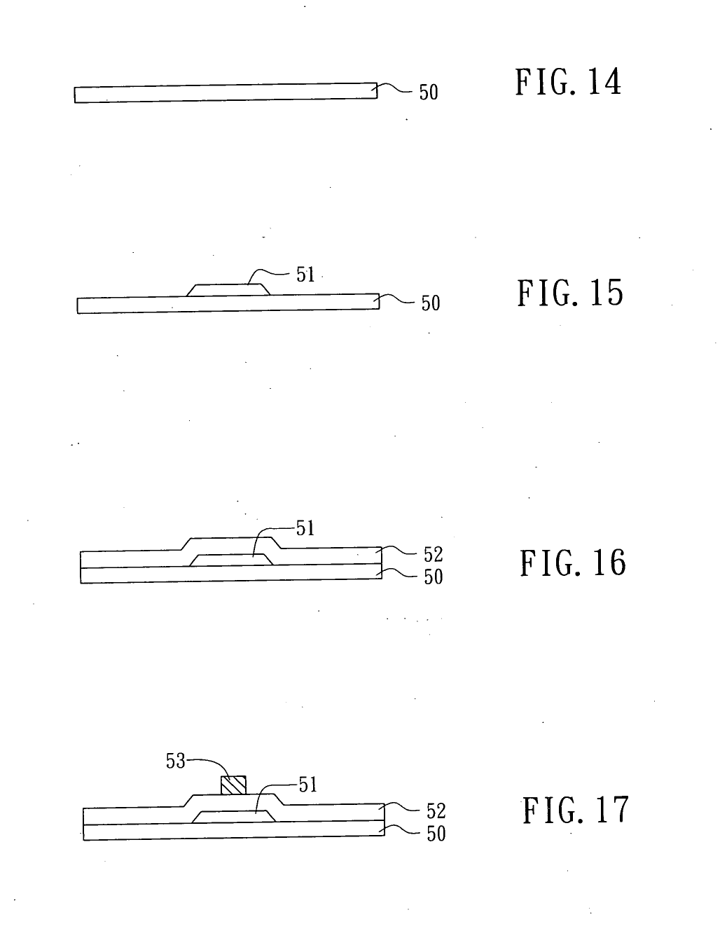

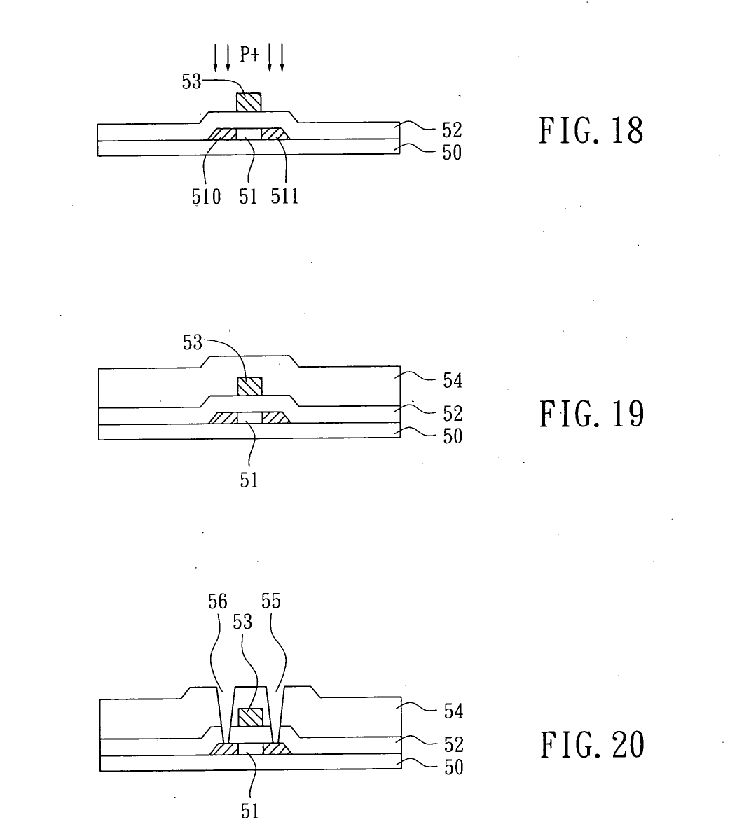

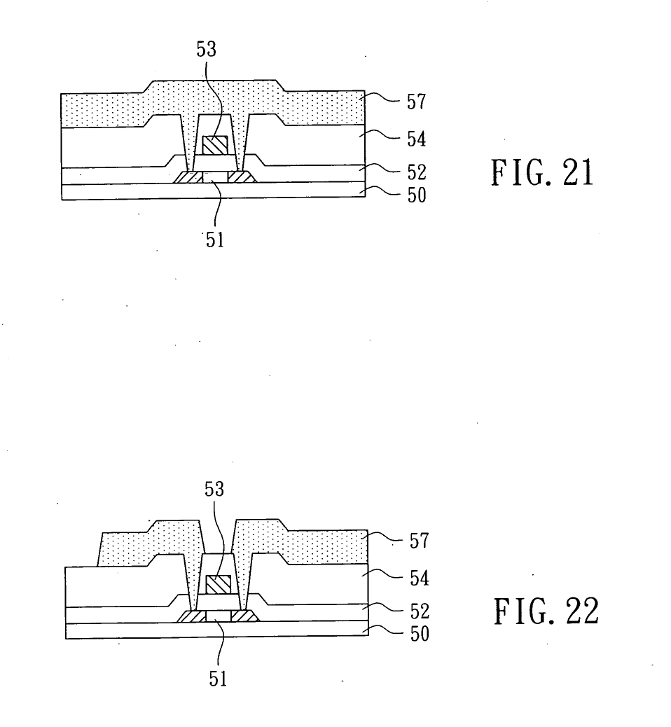

Please further refer to FIG. 14 to FIG. 22, which are cross-sectional views showing a method for manufacturing a thin-film transistor in accordance with a second embodiment of the present invention. In FIG. 14, a substrate 50 is provided. In FIG. 15, a poly-silicon mesa 51 is formed on the substrate 50 using a first mask (not shown). Then, an insulating layer 52 is formed on the substrate 50, wherein the insulating layer 52 covers the poly-silicon mesa 51, as shown in FIG. 16. In FIG. 17, a gate metal layer 53 is formed on the insulating layer 52 corresponding to the poly-silicon mesa 51 using a second mask (not shown). In FIG. 18, the poly-silicon mesa 51 is doped with a p-type dopant using self-aligned ion implantation so as to form electrode regions 510 and 511 on the poly-silicon mesa 51. In FIG. 19, a dielectric layer 54 capable of color filtering is formed on the insulating layer 52, wherein the dielectric layer 54 covers the gate metal layer 53. Then, contact holes 55 and 56 are formed in the dielectric layer 54 using a third mask (not shown), wherein the contact holes 55 and 56 penetrate the dielectric layer 54 and the insulating layer 52 so as to contact the poly-silicon mesa 51, as shown in FIG. 20. A conductive layer 57 is formed on the dielectric layer 54 so as to cover the dielectric layer 54 and fill the contact holes 55 and 56, as shown in FIG. 21. In FIG. 22, the conductive layer 57 is etched using a fourth mask (not shown) so as to form circuitry required.

Accordingly, only four masks are required to form a p-channel thin-film transistor capable of color filtering.

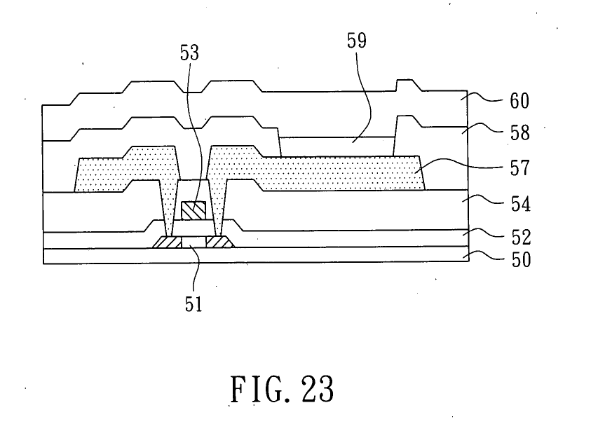

Please to FIG. 23, which is a cross-sectional view showing a p-channel thin-film transistor coupled to an organic light-emitting diode in accordance with the present invention. In FIG. 23, elements labeled in the same way as in the second embodiment are identical to those in the second embodiment and thus detailed description thereof is omitted. A conductive layer 57 is used as a bottom electrode of an organic light-emitting diode 59. A dielectric layer 58 is formed on the conductive layer 57, which is coupled to the organic light-emitting diode 59. The an organic light-emitting diode 59 is further coupled to an electrode layer 60, which is used as a top electrode of the organic light-emitting diode 59.

In the second embodiment of the present invention, an n-channel thin-film transistor can also be formed using the same method so as to reduce the number of masks and manufacturing cost. Preferably, the conductive layer is made of metal, and the substrate is made of one material selected from a group comprising glass, plastic, quartz, silicon and stainless steel.

On the other hand, in the prior art, there are required three organic light-emitting diodes, each with one of RGB colors, respectively. Under such circumstances, incoherent color aging occurs due to different lifetimes of these organic light-emitting diodes. In the present invention, the monochromatic organic light-emitting diode is used with the thin-film transistor capable of color filtering so as to avoid incoherent color aging.

According to the above discussion, the present invention discloses a thin-film transistor (TFT) for driving an organic light-emitting diode (OLED) and a method for manufacturing the thin-film transistor using a dielectric layer capable of color filtering with a monochromatic organic light-emitting diode so as to avoid incoherent color aging. Therefore, the present invention has been examined to be new, non-obvious and useful.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A thin-film transistor (TFT), comprising:
a substrate;
a first poly-silicon mesa formed on said substrate;
an insulating layer formed on said substrate and covering said first poly-silicon mesa;
a gate metal layer formed on said insulating layer;
a color-filtering dielectric layer formed on said insulating layer and covering said gate metal layer, said dielectric layer being provided with a plurality of contact holes penetrating through said dielectric layer and said insulating layer; and
a conductive layer formed on said dielectric layer and coupled to said first poly-silicon mesa through said contact holes.

2. The thin-film transistor as recited in claim 1, wherein said first poly-silicon mesa is p-type.

3. The thin-film transistor as recited in claim 2, further comprising an n-type second poly-silicon mesa formed on said substrate and covered by said insulating layer, wherein said conductive layer is coupled to said second poly-silicon mesa through said contact holes.

4. The thin-film transistor as recited in claim 1, wherein said first poly-silicon mesa is n-type.

5. The thin-film transistor as recited in claim 1, wherein said substrate is transparent.

6. The thin-film transistor as recited in claim 1, wherein said substrate is made of one material selected from a group comprising glass, plastic, quartz, silicon and stainless steel.

7. The thin-film transistor as recited in claim 1, wherein said conductive layer is made of metal.

8. A method for manufacturing a thin-film transistor (TFT), said method comprising steps of:
providing a substrate;
forming a first poly-silicon mesa and a second poly-silicon mesa on said substrate;
doping said first poly-silicon mesa with an n-type dopant using ion implantation;
forming an insulating layer on said substrate, said insulating layer covering said first poly-silicon mesa and said second poly-silicon mesa;
forming a gate metal layer on said insulating layer corresponding to said first poly-silicon mesa and said second poly-silicon mesa;
doping said first poly-silicon mesa with an n-type dopant using ion implantation;
doping said second poly-silicon mesa with a p-type dopant using ion implantation;
forming a dielectric layer capable of color filtering on said insulating layer, said dielectric layer covering said gate metal layer;
forming a plurality of contact holes in said dielectric layer, said plurality of contact holes penetrating said dielectric layer and said insulating layer so as to contact said first poly-silicon mesa and said second poly-silicon mesa;
forming a conductive layer on said dielectric layer; and
etching said conductive layer.

9. The method as recited in claim 8, wherein said substrate is transparent.

10. The method as recited in claim 8, wherein said substrate is made of one material selected from a group comprising glass, plastic, quartz, silicon and stainless steel.

11. The method as recited in claim 8, wherein said conductive layer is made of metal.

12. A method for manufacturing a thin-film transistor (TFT), said method comprising:
providing a substrate;
forming a poly-silicon mesa on said substrate;
forming an insulating layer on said substrate, said insulating layer covering said poly-silicon mesa;
forming a gate metal layer on said insulating layer corresponding to said poly-silicon mesa;
doping said poly-silicon mesa with an p-type dopant using ion implantation;
forming a dielectric layer capable of color filtering on said insulating layer, said dielectric layer covering said gate metal layer;
forming a plurality of contact holes in said dielectric layer, said plurality of contact holes penetrating said dielectric layer and said insulating layer so as to contact said poly-silicon mesa;
forming a conductive layer on said dielectric layer; and
etching said conductive layer.

13. The method as recited in claim 12, wherein said substrate is transparent.

14. The method as recited in claim 12, wherein said substrate is made of one material selected from a group comprising glass, plastic, quartz, silicon and stainless steel.

15. The method as recited in claim 12, wherein said conductive layer is made of metal.
